(19) United States
(12) Patent Application Publication
(10) Pub. No.: US 2026/0144168 A1
(43) Pub. Date: May 21, 2026

(54) HYBRID BONDING WITH MIXED PITCH CONTACT PADS

(71) Applicant: ADEIA SEMICONDUCTOR BONDING TECHNOLOGIES INC., San Jose, CA (US)

(72) Inventors: Guilian Gao, Campbell, CA (US); Belgacem Haba, Saratoga, CA (US); Cyprian Emeka Uzoh, San Jose, CA (US); Thomas Workman, San Jose, CA (US)

(21) Appl. No.: 19/000,323

(22) Filed: Dec. 23, 2024

Related U.S. Application Data
(60) Provisional application No. 63/722,486, filed on Nov. 19, 2024.

(51) Int. Cl. H01L 23/00; H01L 23/498

(52) U.S. Cl. CPC H10W 90/701; H10W 72/9445; H10W 90/794

(57) ABSTRACT

A microelectronic assembly is disclosed comprising an interconnect structure having a first plurality of conductive features with a large pitch and a second plurality of conductive features with a small pitch. A first element is hybrid bonded to a first side of the interconnect structure having a first contact pad directly bonded to a conductive feature of the second plurality of conductive features. A second element is hybrid bonded to the first side of the interconnect structure with a second contact pad directly bonded to a conductive feature of the interconnect structure and electrically connected to the first contact pad. In some embodiments, the electrical connection between the first contact pad and the second contact pad is through a conductive trace disposed in the interconnect structure. In some embodiments, the electrical connection is via a bridge die hybrid bonded to a second side of the interconnect structure.

### PRIORITY CLAIM AND CROSS-REFERENCE TO RELATED APPLICATION

This application claims the benefit under 35 U.S.C. § 119(e)(1) of U.S. Provisional Application No. 63/722,486, filed Nov. 19, 2024, the entire contents of all of which are hereby incorporated by reference in their entirety.

### BACKGROUND

### Field

The field relates to hybrid bonding of semiconductor elements, and especially relates to forming a hybrid bonded structure having coarse pitch and fine pitch contact pads.

### Description of the Related Art

As the semiconductor industry looks to enhance device performance by scaling system-level interconnections, hybrid bonding provides a promising solution with the ability to integrate a plurality of dies with small interconnection pitches of metal contact pads. Conventionally these metal contact pads are embedded in a dielectric layer forming part of a bonding surface. The contact pads generally have uniform or similar inter-pad pitches or contact pad widths.

### SUMMARY

In one aspect of the disclosed embodiments, a microelectronic assembly comprises an interconnect structure including one or more dielectric layers with embedded conductive traces, a first element having a first plurality of contact features with a minimum pitch and a second plurality of contact features with a maximum pitch, and a second element. The first element is hybrid bonded to the interconnect structure such that the first plurality of contact features is directly bonded to a third plurality of contact features of the interconnect structure and the second plurality of contact features is directly bonded to a fourth plurality of contact features of the interconnect structure. The second element is hybrid bonded to the interconnect structure. A conductive trace embedded in the one or more dielectric layers electrically connects the second element with a first contact feature of the first plurality of contact features.

In various embodiments, the minimum pitch of the first plurality of contact features is at least 100% larger than the maximum pitch of the second plurality of contact features. In some embodiments, the minimum pitch of the first plurality of contact features is greater than 5 μm, and maximum pitch of the second plurality of contact features is smaller than 3 μm. In some embodiments, a minimum diameter of the first plurality of contact features is at least 50% larger than a maximum diameter of the second plurality of contact features.

In various embodiments, the one or more dielectric layers comprise silicon oxide.

In various embodiments, a plurality of conductive traces embedded in the one or more dielectric layers electrically connect the second element with the second plurality of contact features.

In various embodiments, the interconnect structure further comprises at least one longitudinal member at least partially embedded in the one or more dielectric layers. The at least one longitudinal member comprises an organic material. In some embodiments, the at least one longitudinal member forms a gridline pattern distributed in the one or more dielectric layers. In some embodiments, the at least one longitudinal member comprises a porous material. In some embodiments, the at least one longitudinal member comprises a polymeric material. In some embodiments, the polymeric material comprises polyimide or polybenzoxazole. In some embodiments, a coefficient of thermal expansion (CTE) of the at least one longitudinal member is at least 2 ppm/° C. In some embodiments, a CTE of the at least one longitudinal member is at least 10 times as much as a CTE of the one or more dielectric layers.

In various embodiments, the microelectronic assembly further comprises a substrate bonded via solder balls to a surface of the interconnect structure. The surface is opposite a bonding surface directly bonded to the first and second elements. In some embodiments, the microelectronic assembly further an underfill material disposed between the interconnect structure and the substrate. The underfill material at least partially surrounds the solder balls. In some embodiments, the underfill material comprises a dielectric material.

In various embodiments, the microelectronic assembly further comprises an encapsulant surrounding the first and second elements and filling voids therebetween. In some embodiments, the encapsulant comprises a dielectric material.

In various embodiments, the first plurality of contact features are positioned in a direction away from the second element, and the second plurality of contact features are positioned in a direction towards the second element.

In another aspect of the disclosed embodiments, a microelectronic assembly comprises an interconnect structure having a first side and a second side opposite the first side, a first element hybrid bonded to the first side of the interconnect structure, a second element hybrid bonded to the first side of the interconnect structure, and a bridge die having an upper surface hybrid bonded to the second side of the interconnect structure. The first side has a first dielectric layer. The second side has a second dielectric layer. At least one organic layer is disposed between the first dielectric layer and the second dielectric layer. The first side comprises a first and a second pluralities of conductive features with a maximum pitch and a third plurality of conductive features with a minimum pitch. The first element haves a fifth plurality of conductive features directly bonded to the first conductive features. The second element has a sixth plurality of conductive features directly bonded to the second plurality of conductive features. The bridge die has a third conductive feature electrically connected to a first conductive feature of the first plurality of conductive features and a fourth conductive feature electrically connected to a second conductive feature of the second plurality of features.

In various embodiments, the minimum pitch of the third plurality of conductive features is at least 100% larger than the maximum pitch of the first and a second pluralities of conductive features. In some embodiments, the maximum pitch of the first and a second plurality of conductive features is smaller than 3 μm, and minimum pitch is larger than 5 μm of the third plurality of conductive features. In some embodiments, a minimum diameter of the third plurality of contact features is at least 50 % larger than a maximum diameter of the first or the second plurality of contact features.

In various embodiments, the at least one organic layer comprises polyimide or polybenzoxazole.

In various embodiments, the microelectronic assembly further comprises at least one metallization layer disposed in the at least one organic layer or between adjacent layers of the at least one organic layer.

In various embodiments, the third conductive feature is directly bonded to a fifth conductive feature formed at the second side of interconnect structure, and the fourth conductive feature is directly bonded to a sixth conductive feature formed at the second side of interconnect structure. The fifth conductive feature is electrically connected to the first conductive feature of the first plurality of conductive features, and the sixth conductive feature is electrically connected to the second conductive feature of the second plurality of conductive features. In some embodiments, the fifth conductive feature is aligned with the first conductive feature and the sixth conductive feature is aligned with the second conductive feature. In some embodiments, the fifth conductive feature is horizontally offset from the first conductive feature, and the sixth conductive feature is horizontally offset from the second conductive feature.

In various embodiments, the first and second dielectric layers comprise silicon oxide.

In various embodiments, the microelectronic assembly further comprises one or more devices directly bonded to the second side of the interconnect structure. In some embodiments, a contact pad of a first device of the one or more devices is electrically connected to a conductive feature of the third plurality of conductive features. In some embodiments, a contact pad of a second device of the one or more devices is electrically connected to a conductive feature of a fourth plurality of conductive features. The fourth plurality of conductive features are embedded in the first surface and having the second minimum pitch.

In various embodiments, the microelectronic assembly further comprises a substrate bonded via solder balls to a surface of the one or more devices. The surface is opposite a bonding surface directly bonded to the second side of the interconnect structure. In some embodiments, the microelectronic assembly further comprises an underfill material disposed between the one or more devices and the substrate. The underfill material at least partially surrounds the solder balls. In some embodiments, the microelectronic assembly further comprises an encapsulating material at least partially embedding the one or more devices and the bridge die, and filling voids therebetween.

In various embodiments, the microelectronic assembly further comprises an encapsulant surrounding the first and second elements and filling voids therebetween.

In various embodiments, the first plurality of conductive features are positioned in a direction towards the second element, the third plurality of conductive features are positioned in a direction away from the second element, and the second plurality of conductive features are positioned in a direction towards the first element.

In another aspect of the disclosed embodiments, a method for forming a microelectronic assembly comprises providing an interconnect structure comprising one or more dielectric layers and having a first side and a second side, forming one or more conductive traces disposed in the one or more dielectric layers, providing a first plurality of contact features with a minimum pitch and a second plurality of contact features with a maximum pitch at the first side and at least partially embedded in the one or more dielectric layers, hybrid bonding a first element to the first side by directly bonding a third plurality of contact features of the first element to the first plurality of contact features and a fourth plurality of contact features of the first element to the second plurality of contact features, and hybrid bonding a second element to the first side by directly bonding a second contact feature of the second element to a first contact feature of the interconnect structure.

In various embodiments, the minimum pitch of the first plurality of contact features is at least 100% larger than the maximum pitch of the second first plurality of contact features. In some embodiments, the minimum pitch of the first plurality of contact features is greater than 5 μm, and maximum pitch of the second first plurality of contact features is smaller than 3 μm.

In various embodiments, the method further comprises electrically connecting the first contact feature to one of the first plurality of features through the one or more conductive traces.

In various embodiments, the method further comprises forming at least one longitudinal member at least partially embedded in the one or more dielectric layers, the at least one longitudinal member comprising an organic material. In some embodiments, the method further comprises the at least one longitudinal member forms a gridline pattern distributed in the at least two dielectric layers. In some embodiments, the at least one longitudinal member comprises a porous material. In some embodiments, a CTE of the at least one longitudinal member is at least 2 ppm/° C. In some embodiments, a CTE of the at least one longitudinal member is at least eight times greater than a CTE of the one or more dielectric layers.

In various embodiments, the method further comprises depositing an encapsulant surrounding the first and second elements and filling voids therebetween.

In various embodiments, the interconnect structure comprising one or more dielectric layers and having a first side and a second side is provided over a carrier. In some embodiments, the carrier is removed after hybrid bonding the first and second elements.

In various embodiments, the method further comprises embedding a fifth plurality of contact features and a sixth plurality of contact features at the second side in the one or more dielectric layers, so that the fifth plurality of contact features are electrically connected to the third plurality of contact features and the sixth plurality of contact features are electrically connected to the fourth plurality of contact features, and hybrid bonding a bridge die to the second side of the interconnect structure, including directly bonding a seventh plurality of contact features on the bridge die to the fifth plurality of contact features, an eighth plurality of contact features on the bridge die to the sixth plurality of contact features, and a fourth contact feature on the bridge die to a third contact feature at the second side of the interconnect structure, the third contact feature electrically connected to the first contact feature.

In various embodiments, the method further comprises forming an organic layer in or between two adjacent layers of the one or more dielectric layers, wherein the one or more conductive traces are disposed within the organic layer. In some embodiments, the organic layer comprise polyimide or polybenzoxazole.

In various embodiments, the method further comprises directly bonding one or more dies to the second side of the interconnect structure. In some embodiments, bonding a substrate via solder balls to the one or more dies. In some embodiments, the method further comprises depositing an underfill material to fill a space between the one or more dies and the substrate, the underfill material at least partially surrounding the solder balls. In some embodiments, the method further comprises depositing an encapsulating material to at least partially embed the one or more dies and the bridge die, and to fill voids therebetween.

In another aspect of the disclosed embodiments, a method for forming a microelectronic assembly comprises providing an interconnect structure comprising a first side and a second side opposite the first side, hybrid bonding a first element to the first side of the interconnect structure, hybrid bonding a second element to the first side of the interconnect structure, and hybrid bonding an upper surface of a bridge die to the second side of the interconnect structure. The first side has a first dielectric layer. The second side has a second dielectric layer. At least one organic layer is disposed between the first dielectric layer and the second dielectric layer. The first side comprises a first and a second pluralities of conductive features with a maximum pitch and a third plurality of conductive features with a minimum pitch. The first element has a fifth plurality of conductive features directly bonded to the first conductive features. The second element has a sixth plurality of conductive features directly bonded to the second plurality of conductive features. The bridge die has a third conductive feature electrically connected to a first conductive feature of the first plurality of conductive features and a fourth conductive feature electrically connected to a second conductive feature of the second plurality of features.

In various embodiments, the minimum pitch of the third plurality of conductive features is at least 100% larger than the maximum pitch of the first and a second pluralities of conductive features. In some embodiments, the maximum pitch of the first and a second pluralities of conductive features is smaller than 3 μm, and the minimum pitch of the third plurality of conductive features is larger than 5 μm.

In various embodiments, the at least one organic layer comprises polyimide or polybenzoxazole.

In various embodiments, the method further comprises forming at least one metallization layer disposed in the at least one organic layer or between adjacent layers of the at least one organic layer.

In various embodiments, the third conductive feature is directly bonded to a fifth conductive feature formed at the second side of interconnect structure, and the fourth conductive feature is directly bonded to a sixth conductive feature formed at the second side of interconnect structure. The fifth conductive feature is electrically connected to the first conductive feature of the first plurality of conductive features, and the sixth conductive feature is electrically connected to the second conductive feature of the second plurality of conductive features.

In various embodiments, the method further comprises hybrid bonding one or more devices to the second side of the interconnect structure. In some embodiments, a contact pad of a first device of the one or more devices is electrically connected to a conductive feature of the third plurality of conductive features, and a contact pad of a second device of the one or more devices is electrically connected to a conductive feature of a fourth plurality of conductive features, the fourth plurality of conductive features embedded in the first surface and having the second minimum pitch. In some embodiments, the method further comprises bonding a substrate bonded via solder balls to an under surface of the one or more devices, the under surface opposite a bonding surface directly bonded to the second side of the interconnect structure. In some embodiments, the method further comprises depositing an underfilling material between the one or more devices and the substrate, the underfill material at least partially surrounding the solder balls. In some embodiments, the method further comprises an encapsulating material at least partially embedding the one or more devices and the bridge die, and filling voids therebetween.

In various embodiments, the method further comprises an encapsulant surrounding the first and second elements and filling voids therebetween.

In various embodiments, the first plurality of conductive features are positioned in a direction towards the second element, the third plurality of conductive features are positioned in a direction away from the second element, and the second plurality of conductive features are positioned in a direction towards the first element.

### BRIEF DESCRIPTION OF THE DRAWINGS

Specific implementations will now be described with reference to the following drawings, which are provided by way of example, and not limitation.

FIG. 1 is a schematic cross-sectional view of two semiconductor elements configured to be hybrid bonded together.

FIG. 2 is a schematic cross-sectional view of a bonded structure comprising the two semiconductor elements of FIG. 1 after hybrid bonding the two semiconductor elements to one another.

FIGS. 3-7 are schematic cross-sectional views illustrating a fabrication method for forming a microelectronic assembly comprising an interconnect structure having a first plurality of conductive features with a large pitch and a second plurality of conductive features with a small pitch hybrid bonded to two or more elements.

FIG. 8 is a flowchart illustrating the fabrication method for forming a microelectronic assembly in accordance with some embodiments shown in FIGS. 3-7.

FIG. 9 is a schematic cross-sectional view illustrating an embodiment of a microelectronic assembly formed by a fabrication method generally similar to the fabrication method illustrated in FIGS. 3-7 and shown in FIG. 8.

FIG. 10 is a schematic plan view of the microelectronic assembly illustrated in FIG. 7 or FIG. 9.

FIGS. 11-14 are schematic cross-sectional views illustrating another fabrication method for forming the microelectronic assembly of FIG. 7.

FIG. 15 is a flowchart illustrating the fabrication method for forming a microelectronic assembly in accordance with some embodiments shown in FIGS. 11-14.

FIGS. 16-21 are schematic cross-sectional views illustrating a fabrication method for forming a microelectronic assembly comprising an interconnect structure having an organic layer disposed therein, a first plurality of conductive features with a large pitch and a second plurality of conductive features with a small pitch hybrid bonded to two or more dies.

FIG. 22 is a schematic plan view of the microelectronic assembly illustrated in FIG. 21.

FIG. 23 is a flowchart illustrating the fabrication method for forming a microelectronic assembly in accordance with some embodiments shown in FIGS. 16-21.

FIGS. 24-26 are schematic cross-sectional views illustrating another fabrication method for forming the microelectronic assembly of FIG. 21.

FIG. 27 is a flowchart illustrating the fabrication method for forming a microelectronic assembly in accordance with some embodiments shown in FIGS. 24-26.

FIG. 28 is a schematic cross-sectional view of at a stage illustrating another fabrication method for forming the microelectronic assembly of FIG. 21.

### DETAILED DESCRIPTION

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

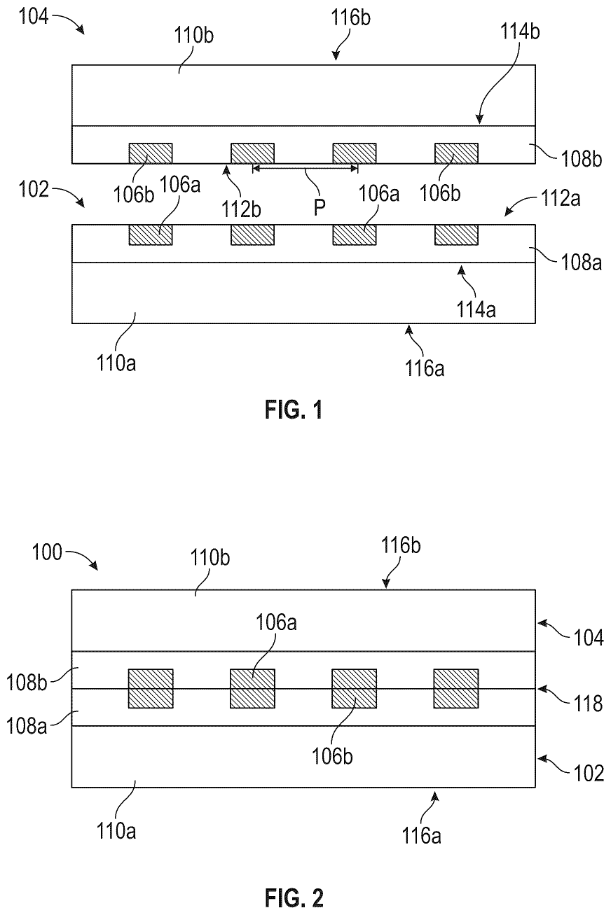

In various embodiments, bonding layers 108a and/or 108b shown in FIG. 1, which will be further described below, can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. patent application Ser. No. 18/391,173, filed Dec. 20, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Many organic adhesives lack strong chemical or covalent bonds with either element. In such processes, the connections between the elements are weak and/or readily reversed, such as by reheating.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 1 and 2 schematically illustrate cross-sectional side views of first and second elements 102, 104 prior to and after, respectively, a process for forming a directly bonded structure, and more particularly a hybrid bonded structure, according to some embodiments. In FIG. 2, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry (not shown) can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, one or both of the elements 102, 104 may not include active circuitry, but may instead comprise dummy elements, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110 b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises other materials, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate (e.g., a laminate substrate, a ceramic substrate, etc.) or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding layers for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding surfaces 112a, 112b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104 after the first and second elements 102, 104 are hybrid bonded to form the bonded structure 100. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially smooths out high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding bonding surfaces, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature. In various embodiments, bonds can form at lower temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1 prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the surface of the feature, and can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the conductive feature is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. In some embodiments, each the conductive features 106a and 106b can comprise a different type of metal or alloy. Or the conductive features 106a and 106b can comprise metals or alloys that have similar but not the same compositions. For example, the conductive features 106a may comprise copper or a copper alloy, but the conductive features 106b may comprise nickel or a nickel alloy. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly through etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

As described above, microelectronic elements, e.g., semiconductor elements (e.g., dies or chips), can be vertically stacked when bonded. In some embodiments, semiconductor elements can be connected side-by-side when bonded. These elements can be connected through an interposer, which can incorporate through substrate vias (TSVs) to connect elements disposed at opposing sides of the interposer. An interposer can also connect two or more elements disposed side-by-side on the same side of the interposer. Another way to connect two or more elements side-by-side is through a bridge, e.g., a bridge die, which can be advantageous if the connection only involves a small field region of each element. For the interposer connection or the bridge connection, conductive features or contact pads are generally uniformly distributed or have similar sizes (e.g., diameters) without significant variation.

The present application discloses a bonded structure, e.g., a microelectronic assembly or semiconductor assembly, that includes an interconnect structure (e.g., an interposer) hybrid bonded to two or more elements, e.g., dies. Directly bonded conductive features, e.g., contact pads, include at least a first plurality of conductive features having a first pitch (e.g., a coarse or large pitch) and a second plurality of conductive features having a second pitch (e.g., a pitch that is finer or smaller than the first pitch). The sizes or diameters of the first plurality of conductive features can be larger than those of the second plurality of conductive features. In some embodiments, the two or more elements are electrically connected by conductive traces laterally embedded in the interconnect structure. In some embodiments, the two or more elements are electrically connected by a bridge die that is hybrid bonded to the opposite side of the interconnect structure. In some embodiments, the large pitch conductive features are configured to facilitate power connections of the two or more elements, and the small pitch conductive features are configured to transmit digital signals from/to the two or more elements. In some embodiments, the interconnect structure includes an organic material, e.g., polymeric material, or a porous material disposed therein for enhanced flexibility and/or thermal expansion so as to provide compensation for stress during thermal events, e.g., annealing. The organic or porous material may be disposed in the interconnect structure as one or more layers between layers of dielectric material of the interconnect structure, or may be disposed as longitudinal members or forming a gridline pattern distributed in the dielectric material of the interconnect structure.

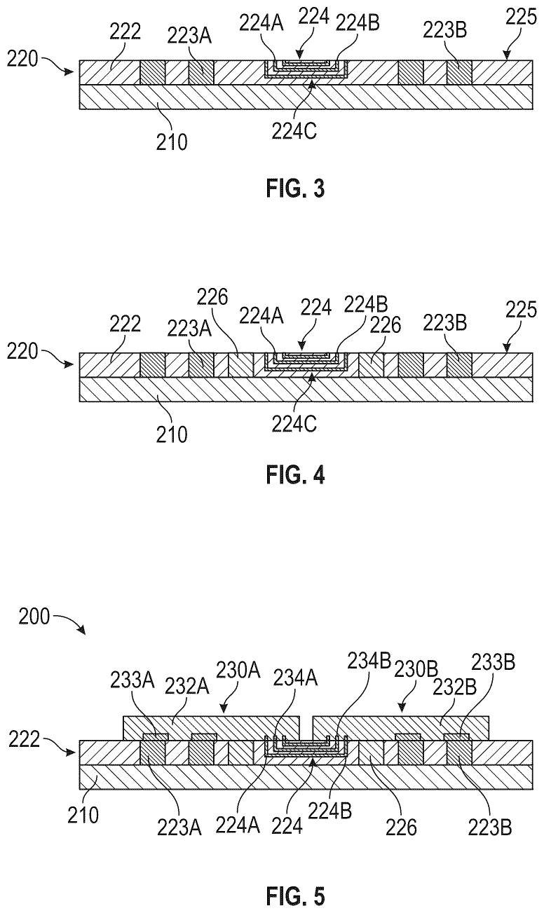

FIGS. 3-7 are schematic cross-sectional views illustrating an example method for fabricating a microelectronic assembly comprising an interconnect structure hybrid bonded to two elements involving conductive features of different pitches as described above. FIG. 3 is a schematic cross-sectional view illustrating an interconnect structure 220 formed over a carrier 210 with a bonding surface 225 facing upward. The interconnect structure 220 can comprise redistribution layers (RDLs) configured for element-to-element bonding. The carrier 210 may comprise a ceramic or dielectric substrate (e.g., a glass substrate), an organic substrate (e.g., a printed circuit board or PCB), a semiconductor substrate (e.g., a silicon substrate), a semiconductor package, or a wafer or panel of other suitable material that may possess desired mechanical properties, e.g., strength, rigidity and hardness to support the interconnect structure for the subsequent fabrication processes.

The interconnect structure 220 comprises one or a plurality of dielectric layers 222 deposited over the carrier 210, a plurality of first conductive features (e.g., contact pads) 223A to the left, a plurality of second conductive features 223B to the right, and a plurality of small dimensioned and closely spaced conductive features 224 in the central field region. The dielectric layer 222 may comprise an inorganic non-conductive material, e.g., silicon oxide, silicon nitride, silicon oxynitride, silicon carbonitride, silicon oxycarbonitride, etc. A thickness of the dielectric layer 222 may be about 10 μm, e.g., in a range of about 3 μm to 12 μm, or in a range of about 5 μm to 15 μm. The conductive features 223A, 223B and 224 may be conductive vias or traces, device or metallization layers exposed at the bonding surface 225, and comprise a metal, such as copper, nickel, chromium, gold, indium, tin, platinum, silver, ruthenium, molybdenum, palladium, cobalt, zinc, tungsten, tantalum, titanium, aluminum, a metal silicide, and alloys thereof, or a non-metal conductive material, e.g., polysilicon, transparent conductive oxide, conducting polymer, or combination thereof.

As can be seen in FIG. 3, the conductive features 223A and 223B have larger sizes or widths and are spaced apart from each other for longer distances as compared to the conductive features 224. In FIG. 3, the conductive features 223A, 223B can have a larger pitch (e.g., a center-to-center distance between adjacent conductive features) than the pitch of the conductive features 224. On the other hand, taking a top view of the interconnect structure 220, as shown in FIG. 10, the conductive features 223A, 223B and 224 may have different shapes, e.g., circular, oval, square, rectangular, polygonal, or closed irregular shapes. A diameter of a conductive feature refers to a maximum dimension across an area of the conductive feature. For a particular interconnect structure 220, each of the plurality of first conductive features 223A may have a different size or diameter, and the distance or pitch between adjacent conductive features may be non-uniform and have distributions among the first conductive features 220. The same is true for the plurality of second conductive features 223B and the plurality of conductive features 224. The size and distance comparison of conductive features embedded in the interconnect structure 220 as described above can therefore be expressed as: a minimum pitch of the conductive features 223A and 223B can be larger than a maximum pitch of the conductive features 224, and a minimum diameter of the conductive features 223A and 223B can be larger than a maximum diameter of the conductive features 224. The minimum pitch of the conductive features 223A and 223B may be more than 100% larger than the maximum pitch of the conductive features 224. In some embodiments, the minimum pitch of the conductive features 223A and 223B can be more than 10 times larger than the maximum pitch of the conductive features 224. For example, the minimum pitch of the conductive features 223A and 223B may be greater than 5 μm, e.g., greater than 20 μm, and the maximum pitch of the conductive features 224 may be smaller than 3 μm, e.g., smaller than 2 μm. The minimum diameter of the conductive features 223A and 223B may be more than 50% larger than the maximum diameter of the conductive features 224. In some embodiments, the minimum diameter of the conductive features 223A and 223B can be more than 10 times larger than the maximum diameter of the conductive features 224. For example, the minimum diameter of the conductive features 223A and 223B may be greater than 3 μm, e.g., greater than 10 μm, and the maximum diameter of the conductive features 224 may be smaller than 3 μm, e.g., smaller than 1 μm.

As can be further seen in FIG. 3, the conductive features 223A and 223B are vias embedded in and penetrating through the dielectric layer 222. On the other hand, the conductive features 224 are partially embedded in the dielectric layer 222. In FIG. 3, different portions of the conductive features 224 are separately denoted as a plurality of third conductive features 224A to the left, a plurality of fourth conductive features 224B to the right, and a plurality of lateral conductive traces 224C connecting the plurality of third conductive features 224A to the plurality of fourth conductive features 224B. While the plurality of third and fourth conductive features 224A, 224B are exposed at the bonding surface 225 (thereby forming contact pads or contact features), the lateral conductive traces 224C are fully embedded within the dielectric layer 222 to provide lateral electrical communication between the conductive features 224A, 224B. As such, no bridge die is needed to connect the plurality of third conductive features 224A to the plurality of fourth conductive features 224B in the embodiment of FIG. 3. Thus, a misalignment issue that may occur when a bridge die is introduced can be avoided. In some embodiments, the lateral conductive traces 224C may be formed by depositing a dielectric material for the dielectric layer 222 and a conductive material for the lateral conductive traces 224C layer-by-layer consecutively, e.g., by a damascene process. The conductive features 223A, 223B, 224A, 224B may be formed by etching the dielectric layer 225 and depositing conductive material into etched cavities. The excessive conductive material then be polished off by CMP. Typically, multiple steps of coating dielectric layers, etching dielectric material, deposition of conductive features, and planarizing conductive features, may be provided to form the conductive features 223A, 223B, 224A, 224B the conductive traces 224C and the dielectric layer 225.

It can be observed that relative to the plurality of first conductive features 223A, the plurality of third conductive features 224A, which are directly bonded to a plurality of first conductive features 234A of a semiconductor element 230A, are positioned proximate a semiconductor element 230B, as will be further described with respect to FIG. 5. Such arrangement may be advantageous to achieve a short length of the lateral conductive traces 224C, which can improve transmission speeds and reduce latency. Likewise, relative to the plurality of second conductive features 223B, the plurality of fourth conductive features 224B, which are directly bonded to a plurality of first conductive features 234B of the semiconductor element 230B, are positioned proximate the semiconductor element 230A.

Referring to FIG. 4, insulating members 226 are embedded in the dielectric layer 222 by etching the dielectric layer 222 from the bonding surface 225 and filling a material of the insulating members 226. The insulating members 226 may penetrate through the thickness of the dielectric layer 222 as shown in FIG. 4, or may be partially embedded in the dielectric layer 222. The insulating members 226 may comprise a porous material, e.g., SICOH dielectric material, porous silicon oxide, or a polymeric material that can deform or change shape so as to release stress, for example, during an annealing process. The insulating members 226 may be disposed in inactive areas, or field regions where a density of conductive features is low. The insulating members 226 may be longitudinal members or may form gridline patterns, as will be further described with respect to FIG. 10 below.

In FIG. 5, after the bonding surface 225 is prepared, e.g., by chemical mechanical polishing (CMP) and activation, the assembly of the interconnect structure 220 coupled with the carrier 210 is directly bonded to two or more devices, for example, two semiconductor elements (e.g., microelectronic or semiconductor devices) 230A, 230B. As such a bonded structure or bonded structure 200 is formed comprising the interconnect structure 220 directly bonded (e.g., hybrid bonded) with the semiconductor elements 230A, 230B. At the process stage of FIG. 5, the bonded structure 200 is attached to the carrier 210.

The semiconductor element 230A comprises a dielectric material layer 232A forming a bonding surface and having a plurality of first contact pads (e.g., conductive pads, conductive features) 233A and a plurality of second contact pads 234A embedded therein and exposed at the bond surface for bonding. Likewise, the semiconductor element 230B comprises a dielectric material layer 232B forming a bonding surface and having a plurality of first contact pads 233B and a plurality of second contact pads 234B embedded therein and exposed at the bond surface for bonding. As described above with respect to the conductive features in the interconnect structure 220, a minimum pitch of the first contact pads 233A, 233B is larger than a maximum pitch of the second contact pads 234A, 234B, and a minimum diameter of the first contact pads 233A,233B is larger than a maximum pitch of the second contact pads 234A, 234B.

During the hybrid bonding process, the dielectric layer 222 of the interconnect structure 220 is directly bonded to the dielectric material layer 232A of the semiconductor element 230A and to the dielectric material layer 232B of the semiconductor element 230B without an intervening adhesive. Likewise, the plurality of first conductive features 223A of the interconnect structure 220 are directly bonded to the plurality of first contact pads 233A of the semiconductor element 230A; the plurality of third conductive features 224A are directly bonded to the plurality of second contact pads 234A of the semiconductor element 230A; the plurality of second conductive features 223B are directly bonded to the plurality of first contact pads 233B of the semiconductor element 230B; the plurality of the fourth conductive features 224B are directly bonded to the plurality of second contact pads 234B of the semiconductor element 230B. After bonding, the assembly of the bonded structure 200 coupled with the carrier 210 can undergo an annealing process to ensure that opposing conductive features or contact pads at the bonding interface are interdiffused and electrical/mechanical connections are established therebetween. In some embodiments, one or both of the semiconductor elements 230A, 230B may be a die or stack of dies. In some embodiments, one or both of the semiconductor elements 230A, 230B may comprise a processor die (e.g., CPU, GPU, NPU, TPU), a memory die or a stack of memory dies (e.g., NAND, high bandwidth memory (HBM)), a photonic integrated circuit (PIC), or a passive device. For example, in some embodiments the semiconductor element 230A can comprise a processor die and the semiconductor element 230B can comprise a memory die or stack of dies (e.g., HBM), or vice versa.

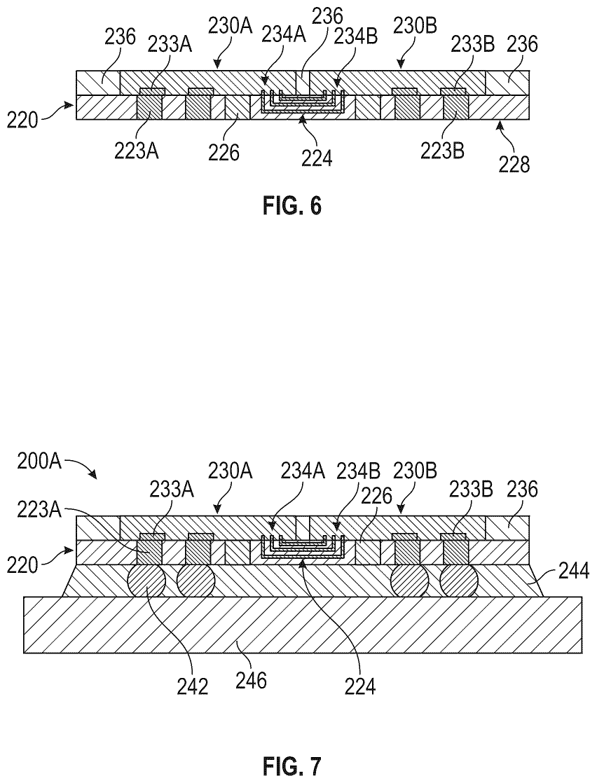

FIG. 6 shows that the semiconductor elements 230A, 230B are encapsulated over the interconnect structure 220 by a dielectric material 236, including filling spaces or voids between the semiconductor elements 230A, 230B. The dielectric material 236 can comprise one or more inorganic dielectric layers (e.g., silicon oxide, silicon nitride, etc.), or one or more organic layers (e.g., molding compound, epoxy, resin, polymer, etc.). In such a way, the bonded structure 200 is reinforced by the dielectric material 236. After the encapsulating process, an excessive portion of the dielectric material 236 on top of the semiconductor elements 230A, 230B (not shown in FIG. 6) may be removed, e.g., by back-grinding and polishing, to expose the backside of the elements. After that, the carrier 210 is removed, as shown in FIG. 6. The removal of the carrier 210 may include one or more of etching, grinding and polishing processes, and optical delayering processes to expose a lower surface 228 of the interconnect structure 220 opposing the bonding surface 225. Mechanical stability of the bonded structure 200 can be further enhanced by attaching a second carrier (which may be subsequently removed) to the expose backside of the semiconductor elements 230A, 230B before the removal of the carrier 210.

Referring now to FIG. 7, the lower surface 228 is prepared and bonded to a substrate (e.g., organic substrate, a printed circuit board or PCB) 246 through solder balls or bumps 242. The solder connections to the substrate 246 may be beneficial for controlling total thickness variation (TTV) of the interconnect structure 220 or the bonded structure 200. The space between the interconnect structure 220 and the substrate 246 may be filled with an underfill material 244. As such a microelectronic assembly 200A is formed comprising the bonded structure 200 and the substrate 246. The underfill material 244 may comprise one or more organic materials (e.g., silica filled epoxy, thermoplastic resin, polymer, etc.), e.g., having a coefficient of thermal coefficient (CTE) less than 20 ppm/° C., less than 15 ppm/° C., less than 10 ppm/° C. Besides functional purposes, e.g., providing power to the semiconductor elements 230A, 230B, the substrate 246 and the underfill material 244 provide substantial mechanical stability to the microelectronic assembly 200A. As illustrated in FIG. 7, the wider conductive features 223A, 223B with coarser pitch are electrically connected to the substrate 246 and may facilitate electrical power transfer. On the other hand, the narrower conductive features 224 with finer pitch electrically connect the semiconductor elements 230A, 230B and may facilitate digital signal transmission therebetween. Although the interconnect structure 220 in FIG. 6 is shown as soldered to the substrate 246, in other embodiments the interconnect structure 220 can be directly bonded (e.g., hybrid bonded) to another element (e.g., a die, substrate, reconstituted element, wafer, etc.).

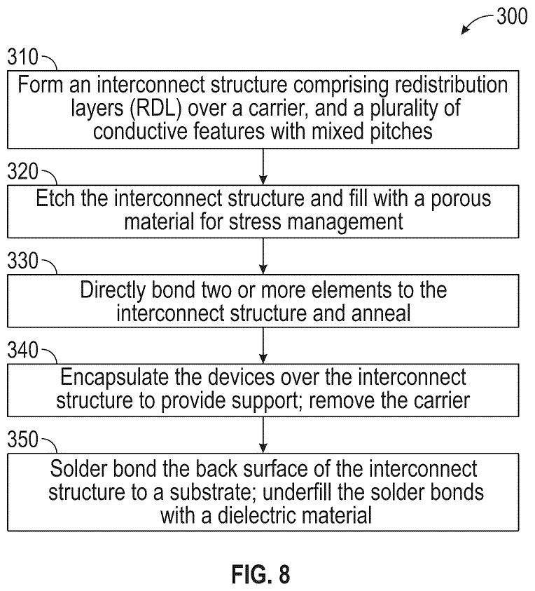

The example fabrication method to fabricate the microelectronic assembly 200A described above with respect to FIGS. 3-7 are further illustrated as a process flowchart 300 shown in FIG. 8. According to flowchart 300, at block 310 an interconnect structure is formed over a carrier. The interconnect structure comprises a dielectric layer with a bonding surface, and a plurality of conductive features having large and small pitches embedded therein. At block 320, the bonding surface is etched, and a porous material is filled into etched cavities. The porous material have properties to release mechanical stress, for example, during an annealing process. At block 330, the interconnect structure is hybrid bonded to two or more microelectronic elements forming a bonded structure. The plurality of conductive features with small pitches are configured to electrically connect the semiconductor elements. Subsequently at block 340, the semiconductor elements are encapsulated over the interconnect structure to strengthen the bonded structure. The carrier is then removed. An excessive portion of the encapsulating material is removed, e.g., by back-grinding, to exposed a back side of each semiconductor element. At block 350, a lower side of the interconnect structure is solder bonded to a substrate to form a microelectronic assembly. The solder bonds between the interconnect structure and the substrate are filled with un underfill material to strength the microelectronic assembly beyond the strengthening by the substrate.

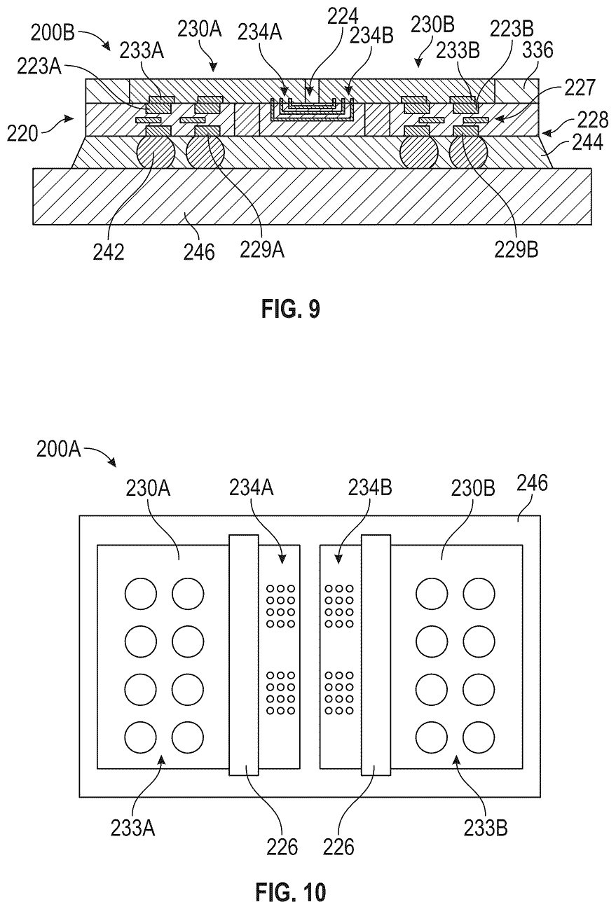

Referring now to FIG. 9, an alternative embodiment of the microelectronic assembly 200A shown in FIG. 7 is illustrated as microelectronic assembly 200B. The microelectronic assembly 200B shares the same structures of the microelectronic assembly 200A, except that the plurality of first conductive features 223A and the plurality of second conductive features 223B are not vias, but partially embedded in the dielectric layer 222. The interconnect structure 220 may have alternating lateral and/or vertical conductors (e.g., metallization layers, device layers) 227 disposed therein. The solder balls 242 may be bonded to a plurality of conductive features 229A, 229B disposed at the lower surface 228 of the interconnect structure 220. The method for fabricating the microelectronic assembly 200B is therefore generally similar to the method illustrated in FIGS. 3-8.

FIG. 10 is a plan view of the microelectronic assembly 200A shown in FIG. 7 or the microelectronic assembly 200 B shown in FIG. 9, as seen in a view through the semiconductor elements 230A, 230B to illustrate the layout of the conductive features 223A, 223B, 224A, 224B and the insulating members 226 disposed in the dielectric layer 222 of the interconnect structure 220. It can be seen that the plurality of first and second conductive features 223A, 223B can form an array or arrays of conductive features with larger diameters and coarser pitches. Likewise, the plurality of third and fourth conductive features 224A, 224B can form an array or arrays of conductive features with smaller diameters and finer pitches. Such combination of larger diameter contact pads with coarser pitches and smaller diameter contact pads with finer pitches may have the advantages of improved yield for fabricating the interconnect structure 220, including the conductive trace layers or RDLs and the bonding surface 225, and of better signal transmitting and power delivery efficiencies, as compared to contact pads of uniform diameter and pitches.

In FIG. 10 the insulating members 226 are longitudinal members extending in one direction. As noted above, the insulating members 226 may be disposed in field regions of low density conductive features. Therefore, the insulating members 226 can be distributed in field regions according to the layout of the conductive features. For example, the insulating members 226 can be distributed as gridline patterns. Such gridline patterns are disclosed in U.S. application Ser. No. 18/806,545, Filed on Aug. 15, 2024, the entire content of which is incorporated by reference herein in its entirety for providing examples of distributing the insulating members in a dielectric member for stressing releasing purposes. Other distribution patterns may include non-continuous or scattered gridline patterns in field regions.

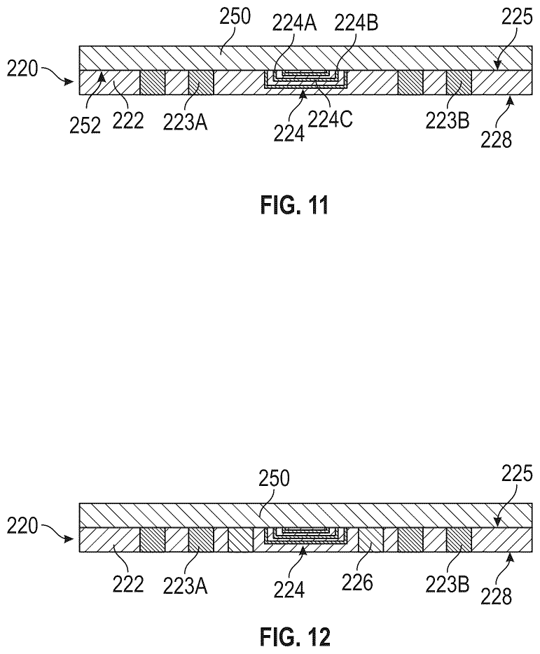

FIGS. 11-14 are schematic cross-sectional views illustrating another example method for fabricating the microelectronic assembly 200A shown in FIG. 7 and the microelectronic assembly 200B shown in FIG. 9. Instead of forming the bonding surface 225 in a subsequent process step, the method starts from depositing a layer of dielectric material and forming the bonding surface 255 over a surface 252 of a carrier 250. Therefore, following this method the sequence of forming the interconnect structure 220 generally starts from forming the layer of dielectric material having the bonding surface 225. An advantage of this method can be that a substantially flat bonding surface 225 can be transferred from the surface of the carrier 250, if the surface of the carrier 250 is well prepared. Methods of pre-forming hybrid bonding surface are disclosed in U.S. application Ser. No. 18/806,545 incorporated by reference herein.

In FIG. 11, the interconnect structure 220 is formed over the carrier 250, with the bonding surface 225 facing and in contact with the carrier 250. Although in FIG. 11 the carrier 250 is shown on top of the interconnect structure 220, during a process the structure can be flipped over with the interconnect structure 220 above the carrier 250. The plurality of first and second conductive features 223A, 223B, which have large diameters and large pitches, are formed as vias through the dielectric layer 222 and are positioned towards the left and right ends of the interconnect structure 220. The plurality of third and fourth conductive features 224A, 224B, which have small diameters and small pitches, are partially embedded in the dielectric layer 222 and exposed at the bonding surface 225. The plurality of third and fourth conductive features 224A, 224B and are positioned in the central region of the interconnect structure 220. The lateral conductive traces 224C are embedded in the dielectric layer 222 to connect the third conductive features 224A to the fourth conductive features 224B. FIG. 12 illustrates that the insulating members 226, which comprise the porous material, are embedded in the dielectric layer 222, as described with respect to FIG. 4.

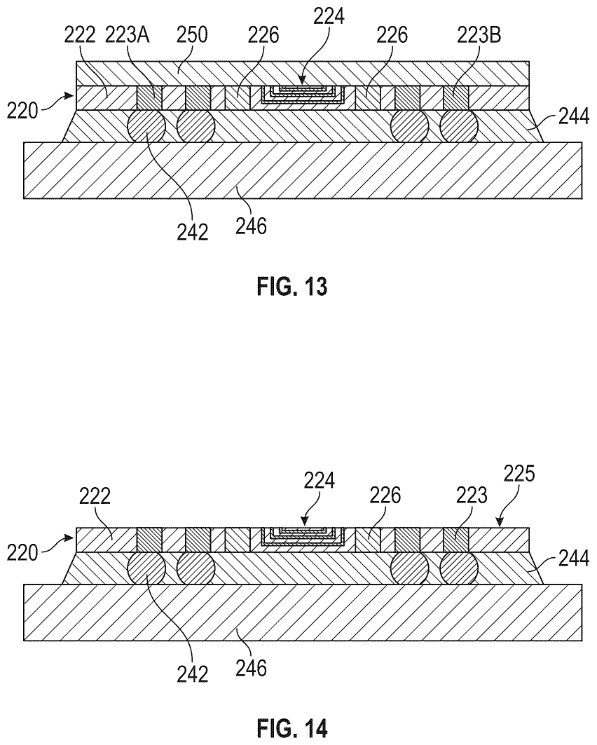

Referring to FIG. 13, the interconnect structure 220 attached the carrier 250 is solder bonded to the substrate 246 with the first and second conductive features 223A, 223B exposed at the lower surface 228 bonded to the solder balls 242. The space between the interconnect structure 220 and the substrate 246 is filled with the underfill material 244. The solder bonding and underfilling process stages are described above with respect to FIG. 7. Then in FIG. 14, the carrier 250 is removed from the interconnect structure 220 to expose the bonding surface 225, similar to the progress stage described with respect to FIG. 6. At the stage of FIG. 14, the interconnect structure 220 is solder bonded and supported by the substrate 246, so as to maintain long range flatness of the bonding surface 225. In other embodiments, the interconnect structure 220 can be hybrid bonded (e.g., directly bonded) to the substrate 246 or an element. As noted above, the solder bonded structure with the substrate 246 is beneficial for absorbing total thickness variation of the interconnect structure 220. Subsequently, the bonding surface 225 is prepared and the interconnect structure 220 is hybrid bonded to two or more semiconductor elements 230A, 230B, as described above with respect to FIG. 5.

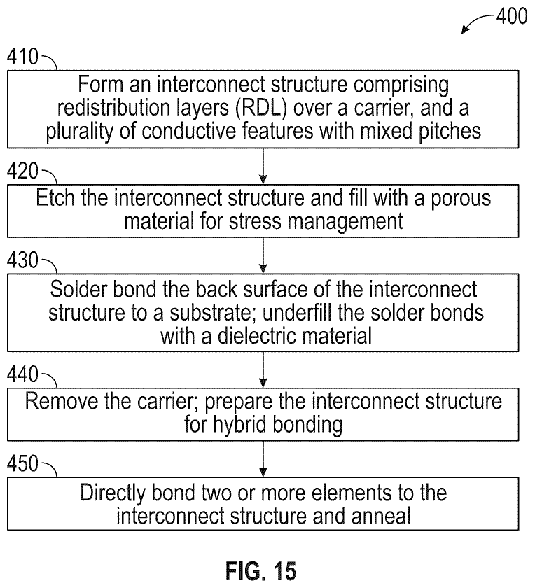

In FIG. 15, the method partially illustrated in FIGS. 11-14 are presented in a fabrication flowchart 400 for making the microelectronic structure 200A schematically shown in FIG. 7. According to flowchart 400, at block 410 an interconnect structure is formed over a carrier. The interconnect structure comprises a dielectric layer having a bonding surface facing and in contact with the carrier, and a plurality of conductive features having large and small pitches therein. At block 420, the dielectric layer is etched, and a porous material is filled into etched cavities. The porous material have properties to release mechanical stress. At block 430, a lower side of the interconnect structure is solder bonded to a substrate to form a microelectronic assembly. The solder bonds between the interconnect structure and the substrate are filled with an underfill material to further strength the microelectronic assembly. Subsequently at block 440, the carrier is removed to expose the bonded surface of the interconnect structure. At block 450, the interconnect structure is hybrid bonded to two or more microelectronic elements. The semiconductor elements are encapsulated over the interconnect structure.

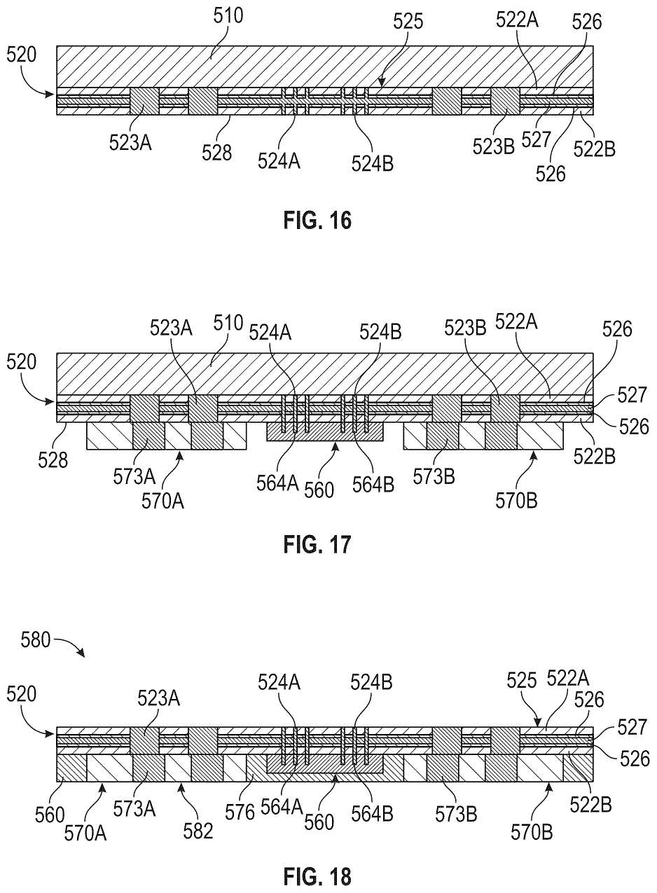

In various embodiments, connections between elements, e.g., dies, can be made through an interconnect structure, e.g., an interposer, coupled with a bridge die. FIGS. 16-22 show schematic cross-sectional and plan transparent views illustrating structures and processes for forming such a microelectronic assembly or bonded structure.

FIG. 16 shows that an interconnect structure 520 is formed over a carrier 510, which provides mechanical support of the interconnect structure 520 which will be transformed to a microelectronic assembly during subsequent processes. Similar to the interconnect structure 220 shown in FIG. 11, a bonding surface 525 of the interconnect structure 520 is formed facing and in contact with a surface of the carrier 510. Such pre-formed bonding surface may be advantageous as described above. The interconnect structure 520 comprises a first dielectric layer 522A having the bonding surface 525, a second dielectric layer 522B, and at least one organic layer 526 disposed between the first and second dielectric layers 522A, 522B. The first and second dielectric layers 522A, 522B may comprise an inorganic dielectric material, e.g., silicon oxide, silicon nitride, or silicon oxynitride. The organic layer 526 may comprise an organic dielectric material, e.g., polymeric material, e.g., polyimide (PI), polybenzoxazole (PBO), benzocyclobutene (BCB) or liquid crystal polymer. At least one metallization layer (e.g., device layer) 527 is disposed in the at least one organic layer 526 or between adjacent layers of the at least one organic layer 526.

There may be a significant difference of coefficient of thermal expansion (CTE) between metallic and inorganic dielectric materials. For example, CTE of pure copper at room temperature is about 16.5 ppm/° C., and for nickel is about 13.3 ppm/° C. However, CTE of thin film silicon dioxide (SiO₂) is about 0.5 ppm/° C. When a metallic conductive layer is formed next to an inorganic dielectric layer or between two dielectric layers, the CTE of the metallic material may be greater than CTE of the inorganic dielectric material by 5 times, 8 times, 10 times, 15 times, 20 times, or more. This significant difference of CTEs can cause significant stress at the interface(s) during a thermal event, e.g., annealing process, and cause damage in dielectric materials with poor thermomechanical properties. The implementation shown in FIG. 16 allows an organic dielectric layer, e.g., polymeric material, to be sandwiched between adjacent metallic layer and inorganic dielectric layer. CTE for polymeric materials, for example, may be in a range of about 5-60 ppm/° C., which may be higher or comparable to the CTE of metallic materials. In addition, an organic material or polymeric material tends to have much lower modulus of elasticity as compared with a metallic material. For example, a modulus of elasticity of certain high performance polymers may range between 2 to 10 GPa, compared with about 130 GPa for copper, a difference of about more than 10 to 50 times. Lower modulus of elasticity means more strain under the same stress, and thus better flexibility. However, the strain of the at least one organic layer 526 is constrained by the much thicker carrier 510 and the stiffer conductive features 523A, 523B, 524A, 524B, the metallization layer 527 and the first and second dielectric layers 522A, 522B. Therefore, without being limited by theory and depending on glass transition temperature of the at least one organic layer 526, during an annealing process when temperature changes, the at least one organic layer 526 shown in FIG. 16 can accommodate the stress due to the difference of CTEs of the first or second dielectric layer 522A, 522B and the at least one metallization layer 526. In some embodiments, the at least one organic layer 526 may act as a compliant layer or stress release layer within the within a temperature range that the at least one organic layer 526 is stable. In some embodiments, the mechanical and thermal properties (e.g., modulus, CTE, etc.) of the at least one organic layer 526 can be improved by incorporating a reinforcing nonconductive particulate matter. A CTE of the nonconductive particulate matter may be smaller than the CTE of the organic material of the at least one organic layer 526. The particulate matter may form more than 3%, more than 10%, more than 30%, but less than 90% of the composition for the at least one organic. A thickness of the at least one organic layer 526 may range between 3 nm to 100 nm.

As shown in FIG. 16, a plurality of first and second conductive features 523A, 523B, which have a first diameter with a first pitch, and a plurality of third and fourth conductive features 524A, 524B, which have a second diameter with a second pitch, are formed as vias through a thickness of the interconnect structure 520 and exposed at the bonding surface 525. The first diameter is larger than the second diameter, and the first pitch is larger than the second pitch. The plurality of first and second conductive features 523A, 523B are positioned towards the left and right ends of the interconnect structure 520, while the plurality of third and fourth conductive features 524A, 524B are positioned in the central region of the interconnect structure 520. As with the pitches and diameters described with respect to FIG. 3, a minimum pitch of the conductive features 523A, 523B may be more than 100% larger than a maximum pitch of the conductive features 524A, 524B. In some embodiments, the minimum pitch of the conductive features 523A and 523B can be more than 10 times larger than the maximum pitch of the conductive features 524A, 524B. For example, the minimum pitch of the conductive features 523A, 523B may be greater than 5 μm, e.g., greater than 20 μm, and the maximum pitch of the conductive features 524A, 524B may be smaller than 3 μm, e.g., smaller than 2 μm. The minimum diameter of the conductive features 523A, 523B may be more than 50% larger than a maximum diameter of the conductive features 524A, 524B. In some embodiments, the minimum diameter of the conductive features 523A and 523B can be more than 10 times larger than the maximum diameter of the conductive features 524A, 524B. For example, the minimum diameter of the conductive features 523A, 523B may be greater than 3 μm, e.g., greater than 10 μm, and the maximum diameter of the conductive features 524A, 524B may be smaller than 3 μm, e.g., smaller than 1 μm.

In FIG. 17, after a lower surface 528 of the second dielectric layer 522B of the interconnect structure 520 opposite the bonding surface 525 is prepared, e.g., by CMP and chemical activation, the lower surface 528 is hybrid bonded to a bridge die 560. The second dielectric layer 522B is directly bonded to a dielectric layer of the bridge die 560, and the plurality of third and fourth conductive features 524A, 524B of the interconnect structure 520 are directly bonded to a plurality of first and second contact pads 564A, 564B of the bridge die 560, respectively. Further, the lower surface 528 of the interconnect structure 520 can be hybrid bonded to at least one microelectronic device, for example, two devices 570A, 570B. The devices 570A, 570B may be passive devices or integrated passive devices (IPDs) and may have pass-through conductive features 573A, 573B, e.g., TSVs or through glass vias (TGVs) for electrical connections, as shown in FIG. 17. In some embodiments, the devices 570A, 570B can be active devices. During the bonding process, the second dielectric layer 522B is directly bonded to a dielectric layer of the device 570A, 570B, respectively. The plurality of first and second conductive features 524A, 524B of the interconnect structure 520 are directly bonded to a plurality of conductive features 573A of the device 570A and to a plurality of conductive features 573B of the device 570B, respectively.

FIG. 18 shows that the bridge die 560 and devices 570A, 570B are encapsulated on the interconnect structure 510 by an encapsulating material 576, including filling spaces or voids therebetween. The encapsulating material 576 can comprise one or more inorganic dielectric layers and organic layers as described above with respect to FIG. 7. As such, an assembly 580 of the interconnect structure 520, bridge die 560 and devices 570A, 570B is reinforced. Then, the carrier 510 is removed, e.g., by one or more of etching, grinding and polishing processes, to expose the bonding surface 525. The flatness of the bonding surface 525 can be better maintained by attaching a second carrier to the assembly 580 before the carrier 510 is removed.

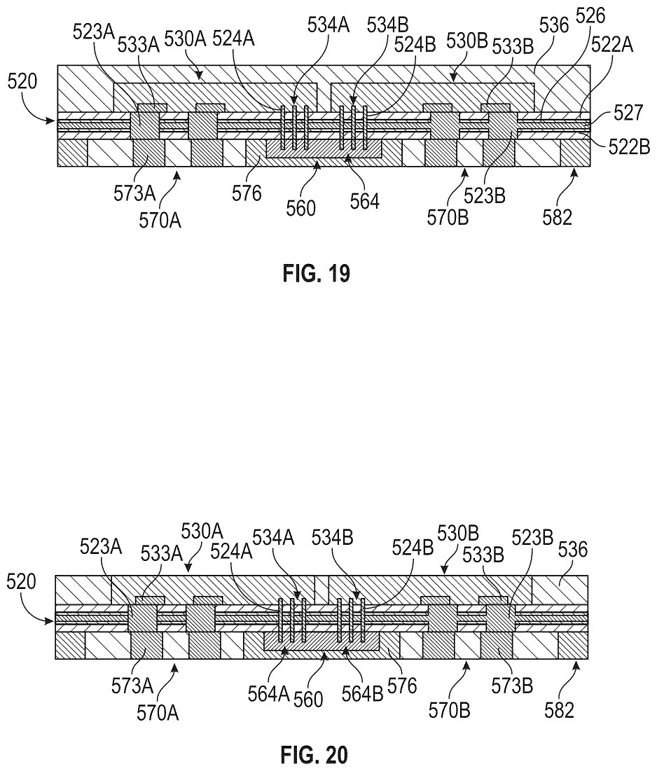

Referring to FIG. 19, the interconnect structure 520 is hybrid bonded to two or more semiconductor elements 530A, 530B, as described above with respect to FIG. 5. Then the semiconductor elements 530A, 530B are encapsulated over the interconnect structure 520 by a dielectric material 536, as described above with respect to FIG. 6. During the hybrid bonding process, the first dielectric layer 522A of the interconnect structure 520 are directly bonded to the dielectric material layer 532A of the semiconductor element 530A and to the dielectric material layer 532B of the semiconductor element 530B without an intervening adhesive. Likewise, the plurality of first conductive features 523A of the interconnect structure 520 are directly bonded to a plurality of first contact pads 533A of the semiconductor element 530A; the plurality of the third conductive features 524A are directly bonded to the plurality of second contact pads 533A of the semiconductor element 530A; the plurality of second conductive features 523B are directly bonded to a plurality of first contact pads 533B of the semiconductor element 530B; the plurality of fourth conductive features 524B are directly bonded to a plurality of second contact pads 533B of the semiconductor element 230B.

In FIG. 20, an excessive portion of the dielectric material 536 laid on top of the semiconductor elements 530A, 530B is removed to expose back surfaces of the semiconductor elements, as described above with respect to FIG. 6.

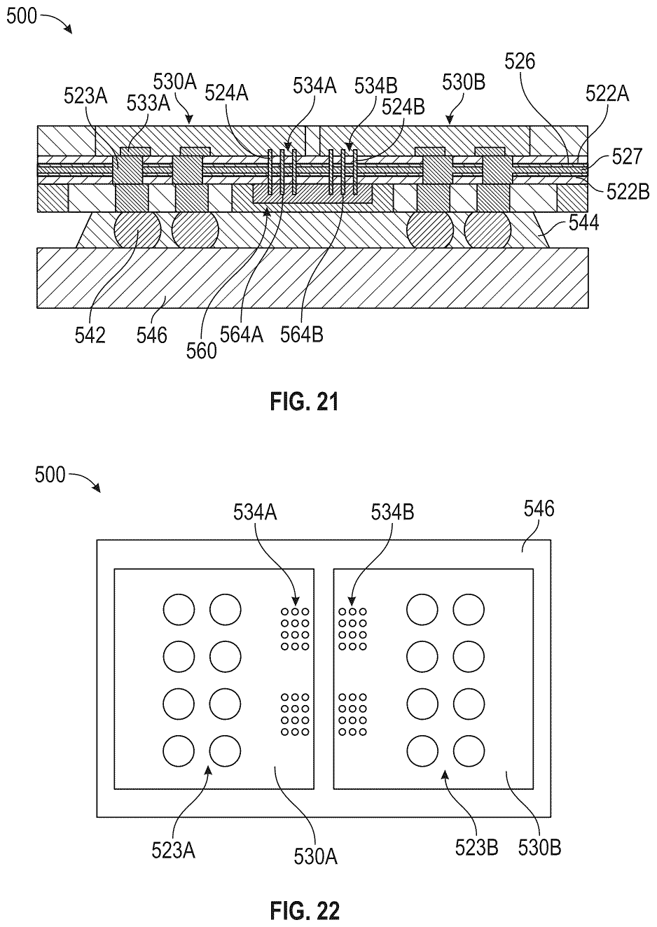

In FIG. 21, a lower surface 582 of the assembly 580 shown in FIG. 20 is prepared and bonded to a substrate 546 through solder balls 542. The space between the devices 570A, 570B and the substrate 546 is filled with an underfill material 544. As such a microelectronic assembly 500 is formed comprising the assembly 580 and the substrate 546. As illustrated, the wider conductive features 523A, 523B in the interconnect structure 520 with coarser pitch are electrically connected to the substrate 546 through the conductive features 573A, 573B in the devices 570A, 570B, respectively. The electrical connections established by wider conductive features 523A, 523B and the conductive features 573A, 573B may be configured as power lines for the semiconductor elements 530A, 530B. On the other hand, the narrower conductive features 524A, 524B with finer pitches are electrically connected to the bridge die 560. These narrower conductive features may be configured as digital signal lines. The narrower conductive features 524A, 524B can alternatively be directly bonded to conductive pads disposed on the substrate 546.

FIG. 22 is a plan view of the microelectronic assembly 500 shown in FIG. 21, as viewed through the semiconductor elements 530A, 530B to illustrate the layout of the conductive features 523A, 523B, 524A, 524B disposed in the interconnect structure 520. As described with respect to FIG. 10, it can be seen that the plurality of first and second conductive features 523A, 523B can form an array or arrays of conductive features with larger diameters and coarser pitches. Likewise, the plurality of third and fourth conductive features 524A, 524B can form an array or arrays of conductive features with smaller diameters and finer pitches.

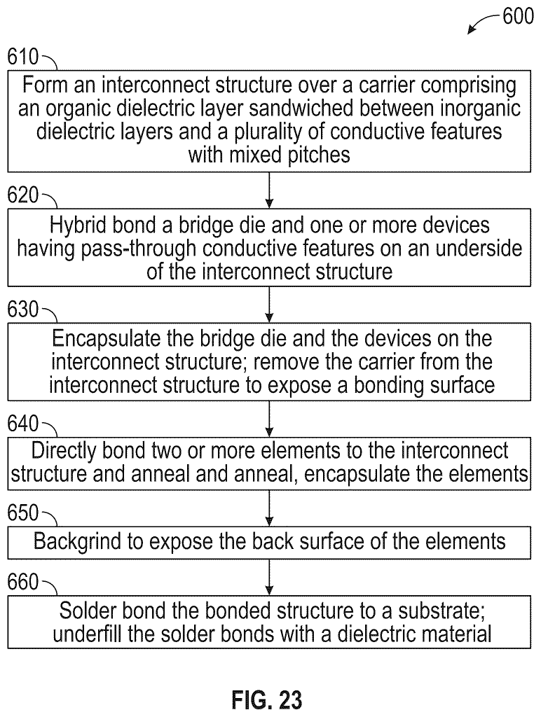

Referring now to FIG. 23, a fabrication process flowchart 600 is illustrated to form the microelectronic assembly 500 schematically shown in FIG. 21, starting from forming the interconnect structure 520 on the carrier 510 schematically shown in FIG. 16. At block 610 of the flowchart 600 an interconnect structure is formed on a carrier with a bonding surface facing and in contact with a surface of the carrier. The interconnect structure comprises a first dielectric layer having the bonding surface, a second dielectric layer, and at least one organic layer disposed between the first and second dielectric layers. At least one metallization layer may be disposed in the at least one organic layer or between adjacent layers of the at least one organic layer. At block 620, a bridge die is hybrid bonded to an underside of the interconnect structure. A plurality of narrower conductive features of the interconnect structure are bonded to a plurality of contact pads on the bridge die. One or more devices having pass-through conductive features may be hybrid bonded to the underside of the interconnect structure. At 630, the bridge die and the one or more devices are encapsulated on the interconnect structure to provide stability. Then the carrier is removed to expose the bonding surface. At block 640, the bonding surface of the interconnect structure is hybrid bonded to two or more semiconductor elements. The two or more semiconductor elements are encapsulated over the interconnect structure. Subsequently at block 650, an excessive portion of the encapsulant material over the semiconductor elements is removed, e.g., by back-grinding, to expose the semiconductor elements. At block 660, the interconnect structure is solder bonded to a substrate to form a microelectronic assembly. The solder bonds are filled with a underfill material to further strength the microelectronic assembly.

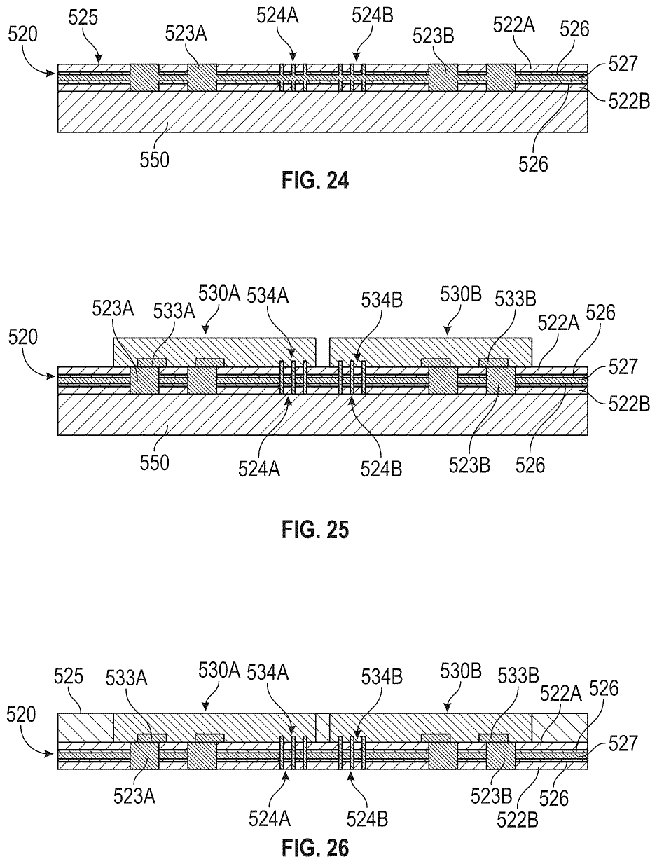

FIGS. 24-26 are schematic cross-sectional views revealing another example method for fabricating the microelectronic assembly 500 shown in FIGS. 21-22. As shown in FIG. 24, instead of forming the interconnect structure 520 with the bonding surface 525 facing the carrier 510, the method follows a reverse order to form the bonding surface 525 as an upper surface. As described with respect to FIG. 16, the plurality of first and second conductive features 523A, 523B, which have large diameters and coarse pitches, and the plurality of third and fourth conductive features 524A, 524B, which have small diameters and fine pitches, are formed as vias through the thickness of the interconnect structure 520 and exposed at the bonding surface 525. The plurality of first and second conductive features 523A, 523B are positioned towards the left and right ends of the interconnect structure 520, respectively, while the plurality of third and fourth conductive features 524A, 524B are positioned in the central region of the interconnect structure 520.

Referring to FIG. 25, two or more semiconductor elements, e.g., two semiconductor elements 530A, 530B, are hybrid bonded to the bonding surface 525 of the interconnect structure 520. Then in FIG. 26, the two semiconductor elements 530A, 530B are encapsulated over the interconnect structure 520 with the dielectric material 536, an excessive portion of the dielectric material 536 over the semiconductor elements 530A, 530B is removed to expose the upper surfaces of the semiconductor elements 530A, 530B, and a carrier 550 is removed to expose the lower surface 528 of the interconnect structure 520. Subsequently, the lower surface 528 of the interconnect structure 520 is hybrid bonded to the bridge die 560 and possibly to one or more semiconductor devices 570A, 570B to form a bonded assembly, as described above with respect to FIGS. 17-18. After that, the bridge die 560 and the devices 570A, 570B are encapsulated. The bonded assembly is solder bonded to a substrate 546 with solder balls 542, and solder balls 542 may be filled with the underfill material 544 to form the microelectronic assembly shown in FIG. 21.

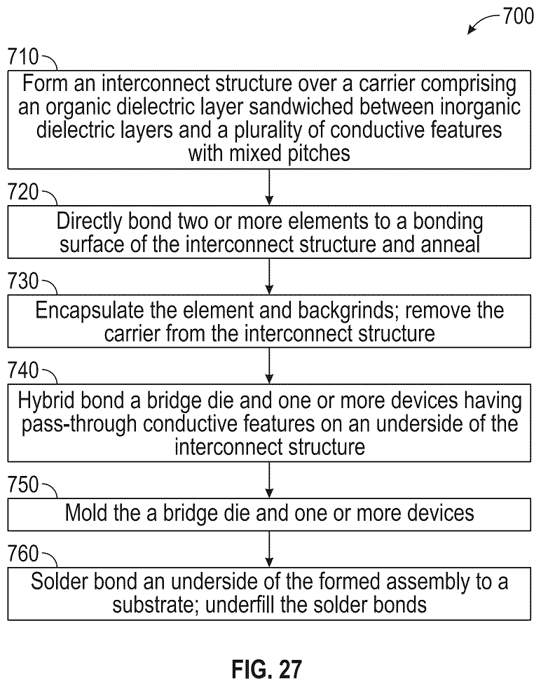

FIG. 27 is a flowchart 700 illustrating the fabrication method partially presented by schematic views shown in FIG. 24-26. At stage 710, an interconnect structure is formed on a carrier with a bonding surface facing upward and away from the carrier. The interconnect structure comprises a first dielectric layer having the bonding surface, a second dielectric layer, and at least one organic layer disposed between the first and second dielectric layers. At least one metallization layer may be disposed in the at least one organic layer or between adjacent layers of the at least one organic layer. At block 720, the interconnect structure is hybrid bonded to two or more semiconductor elements. At block 730, the two or more semiconductor elements are encapsulated over the interconnect structure, and extra encapsulating material over the two or more semiconductor elements is removed to expose the semiconductor elements. The carrier is removed to expose an underside of the interconnect structure. Subsequently at 740, a bridge die is hybrid bonded to the underside of the interconnect structure. One or more devices having pass-through conductive features may be hybrid bonded to the underside of the interconnect structure. At 750, the bridge die and the one or more devices are encapsulated on the interconnect structure to provide stability. At block 640, the interconnect structure with the bridge die and one or more devices is solder bonded to a substrate to form a microelectronic assembly. The solder bonds are filled with a underfill material to further strength the microelectronic assembly.

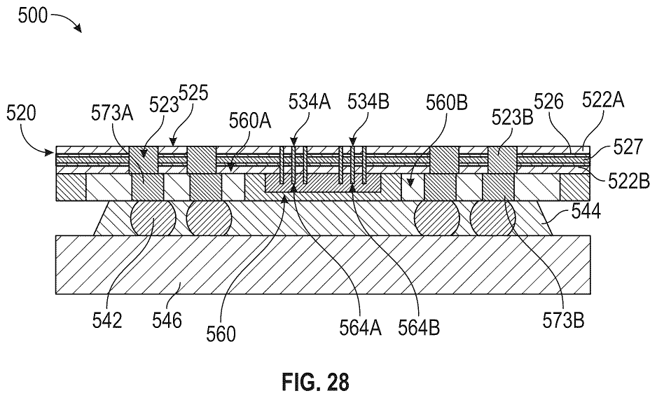

Other fabrication methods can be adopted for forming the microelectronic assembly 200A shown in FIG. 7 or 200B shown in FIG. 9, or forming the microelectronic assembly 500 shown in FIG. 21 without deviating the spirit of this disclosure. For example, FIG. 28 illustrates an immediate stage of an example fabrication method for fabricating the microelectronic assembly 500 shown in FIG. 21. As can be seen, the fabrication method have the interconnect structure 520 formed and solder bonded to the substrate 542 before hybrid bonding the semiconductor elements 530A, 530B shown in FIG. 21 to the bonding surface 525 of the interconnect structure 520. Each fabrication method described herein may have own advantages and disadvantages. For example, the fabrication method represented by the schematic cross-sectional view of FIG. 28 may be advantageous for reducing waste, but may face challenges for maintaining the flatness of the bonding surface 525 for hybrid bonding and for thermal energy management for annealing after hybrid bonding.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A microelectronic assembly, comprising:
an interconnect structure comprising one or more dielectric layers with embedded conductive traces;
a first element having a first plurality of contact features with a minimum pitch and a second plurality of contact features with a maximum pitch, the first element hybrid bonded to the interconnect structure such that the first plurality of contact features is directly bonded to a third plurality of contact features of the interconnect structure and the second plurality of contact features is directly bonded to a fourth plurality of contact features of the interconnect structure; and
a second element hybrid bonded to the interconnect structure, wherein a conductive trace embedded in the one or more dielectric layers electrically connects the second element with a first contact feature of the first plurality of contact features.

2. The microelectronic assembly of claim 1, wherein the minimum pitch of the first plurality of contact features is at least 100% larger than the maximum pitch of the second plurality of contact features.

3. The microelectronic assembly of claim 1, wherein the minimum pitch of the first plurality of contact features is greater than 5 μm, and the maximum pitch of the second plurality of contact features is smaller than 3 μm.

4. The microelectronic assembly of claim 1, wherein a minimum diameter of the first plurality of contact features is at least 50% larger than a maximum diameter of the second plurality of contact features.

5. (canceled)

6. The microelectronic assembly of claim 1, wherein a plurality of conductive traces embedded in the one or more dielectric layers electrically connect the second element with the second plurality of contact features.

7. The microelectronic assembly of claim 1, wherein the interconnect structure further comprises at least one longitudinal member at least partially embedded in the one or more dielectric layers, the at least one longitudinal member comprising an organic material.

8. The microelectronic assembly of claim 7, wherein the at least one longitudinal member forms a gridline pattern distributed in the one or more dielectric layers.

9. (canceled)

10. The microelectronic assembly of claim 7, wherein the at least one longitudinal member comprises a polymeric material.

11. The microelectronic assembly of claim 10, wherein the polymeric material comprises polyimide or polybenzoxazole.

12. The microelectronic assembly of claim 7, wherein a coefficient of thermal expansion (CTE) of the at least one longitudinal member is at least 2 ppm/° C.

13-18. (canceled)

19. The microelectronic assembly of claim 1, wherein the first plurality of contact features are positioned in a direction away from the second element, and the second plurality of contact features are positioned in a direction towards the second element.

20. A microelectronic assembly, comprising:
an interconnect structure comprising a first side having a first dielectric layer, a second side opposite the first side having a second dielectric layer, and at least one organic layer disposed between the first dielectric layer and the second dielectric layer, the first side comprising a first and a second pluralities of conductive features with a maximum pitch and a third plurality of conductive features with a minimum pitch;
a first element hybrid bonded to the first side of the interconnect structure, the first element having a fifth plurality of conductive features directly bonded to the first conductive features;
a second element hybrid bonded to the first side of the interconnect structure, the second element having a sixth plurality of conductive features directly bonded to the second plurality of conductive features; and
a bridge die having an upper surface hybrid bonded to the second side of the interconnect structure, the bridge die having a third conductive feature electrically connected to a first conductive feature of the first plurality of conductive features and a fourth conductive feature electrically connected to a second conductive feature of the second plurality of features.

21-25. (canceled)

26. The microelectronic assembly of claim 20, wherein the third conductive feature is directly bonded to a fifth conductive feature formed at the second side of interconnect structure, the fourth conductive feature is directly bonded to a sixth conductive feature formed at the second side of interconnect structure, the fifth conductive feature electrically connected to the first conductive feature of the first plurality of conductive features, and the sixth conductive feature electrically connected to the second conductive feature of the second plurality of conductive features.

27. The microelectronic assembly of claim 26, wherein the fifth conductive feature is aligned with the first conductive feature and the sixth conductive feature is aligned with the second conductive feature.

28. The microelectronic assembly of claim 26, wherein the fifth conductive feature is horizontally offset from the first conductive feature, and the sixth conductive feature is horizontally offset from the second conductive feature.

29. (canceled)

30. The microelectronic assembly of claim 20, further comprising one or more devices directly bonded to the second side of the interconnect structure.

31. (canceled)

32. (canceled)

33. The microelectronic assembly of claim 30, further comprising a substrate bonded via solder balls to a surface of the one or more devices, the surface opposite a bonding surface directly bonded to the second side of the interconnect structure.

34. The microelectronic assembly of claim 33, further comprising an underfill material disposed between the one or more devices and the substrate, the underfill material at least partially surrounding the solder balls.

35. The microelectronic assembly of claim 33, further comprising an encapsulating material at least partially embedding the one or more devices and the bridge die, and filling voids therebetween.

36. The microelectronic assembly of claim 20, further comprising an encapsulant surrounding the first and second elements and filling voids therebetween.

37-69. (canceled)
